(19) United States
(12) Patent Application Publication
(10) Pub. No.: US 2011/0165772 A1
(43) Pub. Date: Jul. 7, 2011

(54) CARRIER SOLVENT COMPOSITIONS, COATINGS COMPOSITIONS, AND METHODS TO PRODUCE THICK POLYMER COATINGS

(75) Inventors: Michael Wayne Quillen, Kingsport, TN (US); Loady Palmer Holbrook, Kingsport, TN (US); Stephanie Ann Roane, Kingsport, TN (US); Dale Edward O'Dell, Blountville, TN (US); John Cleaon Moore, Camarillo, CA (US)

(73) Assignee: EASTMAN CHEMICAL COMPANY, Kingsport, TN (US)

(21) Appl. No.: 13/047,377

(22) Filed: Mar. 14, 2011

Related U.S. Application Data
(62) Division of application No. 12/336,593, filed on Dec. 17, 2008.

(51) Int. Cl. H01L 21/28; H01L 21/31

(52) U.S. Cl. 438/612; 438/780; 257/E21.158; 257/E21.24

(57) ABSTRACT

Compositions and methods useful for the coating of polymeric materials onto substrates, for example, electronic device substrates such as semiconductor wafers, are provided. These compositions and methods are particularly suitable manipulating thickness of a polymeric coating in a single coating event. Such methods to control photoresist thickness are used to facilitate the layering of electronic circuitry in a three-dimensional fashion. Furthermore, the compositions of the present invention may be effectively used to deposit thick films of polymeric material in a uniform manner onto inorganic substrates which provides a significant benefit over conventional systems.

### CROSS REFERENCE TO RELATED APPLICATIONS

This application is a divisional of U.S. Non-Provisional application Ser. No. 12/336,593, filed on Dec. 17, 2008, the disclosure of which is incorporated herein by reference in its entirety.

### FIELD OF THE INVENTION

The present invention relates generally to the production of thick polymer films. In particular, the present invention relates to carrier solvent compositions, coating compositions and methods to produce thick and uniform polymer films which represent resins used to formulate photoresists for patterning electronic devices on substrates such as semiconductor wafers.

### BACKGROUND OF THE INVENTION

Various materials containing polymers are used in the manufacture of electronic devices. Photoresists, for example, are used throughout semiconductor device fabrication in photolithographic and photomasking operations. The resist is exposed to actinic radiation through a photomask. In the case of a positive-acting material, the exposed regions undergo a chemical reaction to produce an acid by-product or de-couple reaction, whereby rinsing with an alkaline developer is possible. For negative-acting material, crosslinking of the polymer occurs in exposed regions while leaving unexposed regions unchanged. The unexposed resist is subject to dissolution by a suitable developer solution to define a resist pattern. In both cases, the resist pattern (mask) may be transferred to underlying layers or the substrate by etching (removal) or deposition (adding) metal or other material. Such a process is used throughout semiconductor device manufacturing to produce a layering of the circuitry in a three-dimensional effect.

Although photoresists may be available as a positive or negative acting variety, it should be further understood that this area of microelectronics represents one of the most sophisticated parts of the business. Generally speaking, photoresists are polymer resins with active components, which are then dissolved in a carrier solvent system. There is an extreme level of detail invested in the formulation of a photoresist system. Positive-acting systems may contain polyhydroxystyrene (PHost) or novolac (cresol, phenol) varieties of resins which range in molecular weight, functionality, and solution concentration. Negative-acting systems may contain acrylics, epoxies, or isoprenes. The additives include photoactive components of the acid generating or free-radical varieties, amine inhibitors, surfactants, and colorants. Many solids levels and viscosities are used to deposit thicknesses ranging from 500 angstroms (Å) to more than 100,000 (Å)=10 microns (um).

An emerging market at the date of this writing is in the area of ion-implantation of the semiconductor wafer substrate, used to change the electrical properties and enhance semiconductor performance. In this process, a semiconductor substrate is coated with a postive-acting photoresist of the PHost variety which uses a chemically-amplified mechanism, known to produce fine resolution geometries. After producing the pattern with substrate openings which generally represent the transistor gate zones, the substrate is subjected to a high dosage ion implant beam of arsenic, boron, or phosphorous at concentrations approaching 1E15 particles per square centimeter with energies near 1000 KeV. The mask is then removed using either a plasma asher, heated piranha chemical strip, or both. Removal of the photoresist mask represents a significant challenge in the industry due to crust formation on the outer layer from the ion implant operation. One way to ease the conditions of cleaning is by thickening the photoresist film, whereby the sidewall surface area of the pattern is enhanced for a chemical-based cleaner to penetrate, swell, and aid removal. Cleaned substrates with the implanted areas cause a desirable condition to occur in the substrate for overall improved device performance. Therefore, thickening a photoresist will aid in during mask cleaning practices.

Another emerging market where photoresists are used in semiconductor manufacturing is in wafer-level-packaging (WLP) bump formation. In a typical WLP bumping process, conductive interconnect bump pads are formed on the wafer front surface. A passivation layer is formed over the bump pads and openings to the pads are formed therein. An under bump metallization (UBM) structure is deposited over the passivation layer and bump pads. A thick photoresist layer, typically on the order of 25 to 120 microns in thickness, is applied to the wafer, followed by exposure and development techniques to form a patterned mask. The mask defines the size and location of vias over the input/output (I/O) pads and UBM structures. A post-exposure bake is conducted at elevated temperature to further cross-link the resist material to increase chemical and thermal resistance. The interconnect bump material is typically deposited on the wafer by electroplating or by screen printing a solder paste in the areas defined by the vias. The mask is removed using a stripper solution, and the UBM structure is etched to remove the metal from the field area around and between interconnect bumps. The bumps are thermally reflowed prior to stripping the resist in the case of a screen printed solder paste, or after stripping for electroplated bumps. The thermal reflow alters the bump profile into a truncated substantially spherical shape and also facilitates uniform grains. An important trend in this area of business is the demand for taller and more densely populated bumps, based upon operation of higher power chips with more I/O junctions. Taller bumps require the use of thicker photoresists.

Another area of significant growth in back-end semiconductor processes involving chip connectivity is the deposition of insulators. As is the primary interest with designing electronic devices, certain metallic routing must be well defined and exist within finite boundaries of conductivity. These metallic lines are bordered by insulators of the polymeric variety. Such polymers include materials present in the polyimide and silicone chemical families. These systems must be deposited with a high uniformity and in some cases must be present in minimum thicknesses which are greater than 5 um (micron). It is desired to coat substrates with insulating polymers with the capability of increasing thickness.

Thick polymer films are also commonly used in the practice of extreme wafer thinning. It is a need to reduce the thickness of the chip substrate to a level that approaches the operating topography of the device. In many cases, this dimension is below 5 um (microns). Customary wafer thicknesses begin in the range of 600-700 um where device building begins. At the stage where the device is completed, it is desired to remove excess substrate in order to minimize thermal degradation during its operation and aid in the practice of 3-D chip-stacking, an observed emerging industry at the time of this writing. Wafer thinning to dimensions of <50 um substrate thickness, although being a common practice in the manufacture of high power chips of the variety of compound semiconductor designed for radio-frequency emittance (e.g. cell phones, radar, etc.), has not been in high volume production, rather, it is done in limited numbers for special applications. With these practices for silicon becoming ever-more a reality, high volume wafer thinning is now a fundamental commercial practice. Wafer thinning requires complete planarization of the wafer topography, with device geometries exceeding 10 um (microns). It is desired to have a method of coating thick polymers onto this surface which leads to planarization for immediate wafer thinning support.

The use of photoresists and other polymer films in microelectronic processing has historically focused on the resin or active components in the mixture. Attention to solvents, if any, is typically reduced to solubility or hazard characteristic. It is generally recognized that limited attention is given to the type of solvents or the benefits which may exist by investigation of their physical chemical properties (e.g. vapor pressure) and exercising options with different materials or mixtures thereof. It has been identified that resin thickness, uniformity, and smoothness in conventional spin-coating processes are diffusion controlled which, in turn, depends upon evaporation rate [Macromolecules, 2001, 34, 4669-4672; J. Appl. Phys., 49(7), July 1978]. Although evaporation rate may depend upon certain process parameters (i.e. rotational speed, temperature, etc.) to enhance thickness, benefits also exist through solvent choice.

In microelectronic manufacturing, spin coating is the method of choice used to apply a thin polymer coating to a substrate. Material is dispensed in the form of a liquid at the center of a substrate and then the coating equipment applies a high rate of circular motion speed. Liquid delivery may be done by a static method, whereby the fluid will “puddle” onto the surface. A dynamic method may also be used where the material is dispensed when the substrate is already in motion. The substrate spins at a known rotation per minute (rpm), which spreads the polymer fluid over the substrate. As the polymer fluid spreads over the surface, it undergoes dynamic changes in rheology due to solvent evaporation, leading to viscosity increase, and fixing of the polymer onto the surface as a thin coating. The polymer fluid is driven from the center to the edge of the substrate by centrifugal force from the applied motion.

Surface tension describes the nature of substrate wetting, a major contributor to good film formation. A liquid is said to wet a substrate when the substrate has equal or higher surface tension than the liquid itself. Surface tension is the force that holds a liquid together and causes it to occupy the smallest possible volume. This is why atomized liquids, or any which are suspended, will form a bead.

In terms of fluid dynamics, spin-coating can be described as the interaction of two bodies, a solid rotating body underneath a liquid body. The friction of the rotating body causes dramatic movement outward from the center to the edge by centrifugal force. The liquid continues movement outward until the viscous adhesion of the fluid equals the frictional force of the moving substrate. Viscous adhesion will increase as the resin fluid undergoes evaporation and viscosity increases. With viscosity increase, frictional forces increase with the underlying moving substrate, and the film begins to fix onto the surface. At this point, the frictional forces in the fluid dominate which leads to limited mobility and further condensation. Continued rotational motion leads to further evaporation and densification, the dominant fluid dynamic of the last stage of coating.

As the polymer coats the surface and is driven to the edge, it will eventually be “spun-off” of the substrate and much of the material will collect in the “spin bowl” of the equipment, where it then drains to a waste receptacle. Film thickness, micro- and macro-uniformity, and adhesion will depend on the nature of the resin and the resin mixture (percent solids, viscosity, solvent vapor pressure, etc.) and the parameters chosen for the coating process. A common practice to achieve thick coatings is to increase the percent resin in a coating composition which invariably increases the viscosity of the coating composition. However, such viscosity increase may result in poor coating performance. In total, the coating process may be viewed as governed by physical-chemical dynamics of wetting, mobility, viscosity, and evaporation.

The manipulation of spin-speed is a common focus of many apparatus used in the microelectronics industry. Substrate rotation will have a direct affect on these properties and produce different coating results. At low spin-speeds, fluid mobility will be low with minor material loss and consequently, coating, fixing, and densification is pushed to the early stages of the coating process resulting in thicker films, typically measured in microns (1 um=1×10⁻⁶ m). However, high spin-speeds will result in high fluid mobility, high material loss, and low fixing and evaporation. High spin-speeds result in thin films, typically measured in angstroms (1 Å=1×10⁻¹⁰ m).

Therefore, a continuing need exists for compositions which utilize simple solvent mixtures and current equipment available to those familiar in the art that will produce thick polymer films and which address one or more of the problems associated with the state of the art.

### SUMMARY OF THE INVENTION

An embodiment of the present invention concerns a carrier solvent composition for the coating of thick films of polymeric material onto a substrate. The carrier solvent comprises a primary solvent or mixture of primary solvents (Component A) at a weight % concentration ranging from 1 to 99%, and a co-solvent or mixture of co-solvents (Component B) at a weight range % concentration ranging from 99-1%. Moreover, the vapor pressure of Component B is greater than the vapor pressure of Component A, and Component B is selected from the group consisting of methyl acetate, ethyl acetate, isopropyl acetate, methyl propionate, ethyl propionate, acetone, methyl ethyl ketone, methyl propyl ketone, and mixtures thereof.

In an embodiment of the composition, the weight % concentration of Component A is from about 90% to about 40% and the weight concentration of component B is from about 10% to about 60%.

In an another embodiment of the composition, the weight % concentration of Component A is from about 40% to about 20% and the weight concentration of component B is from about 60% to about 80%.

In another embodiment of the composition, the vapor pressure of Component B is at least 10 ton greater than the vapor pressure of Component A.

In another embodiment of the composition, Component A is one or more esters selected from the group consisting of structures (I) R—CO₂R₁, (II) R₂—CO₂C₂H₄OC₂H₄—OR₃, R₄OCO₂R₅, (IV) R₆OH, (V) R₇OC₂H₄OC₂H₄OH, (VI) R₈OC₂H₄OH₅ and (VII) R₉COR₁₀; wherein R, R₁, R₂, R₃, R₄, R₅, R₆, R₇, R₈, R₉, and R₁₀ are independently selected from C₁-C₈-alkyl groups; wherein R, R₁, R₉, R₁₀ are independently selected from C₁ to C₈ alkyl groups, but with the provision that both R and R₁ cannot represent a methyl group and both R₉ and R₁₀ cannot represent a methyl group.

In an embodiment of the composition, component B is methyl acetate or acetone.

In yet another embodiment of the composition component A is a single solvent or represents 2 or more solvents.

Another embodiment concerns a coating composition. The coating composition comprises a polymer resin, a primary solvent or mixture of primary solvents (Component A) at a weight % concentration ranging from 1 to 99%, and a co-solvent or mixture of co-solvents (Component B) at a weight range % concentration ranging from 99-1%. Moreover, the vapor pressure of Component B is greater than the vapor pressure of Component A, and Component B is selected from the group consisting of methyl acetate, ethyl acetate, isopropyl acetate, methyl propionate, ethyl propionate, acetone, methyl ethyl ketone, methyl propyl ketone, and mixtures thereof.

In another embodiment of the coating composition, the weight % concentration of Component A is from about 90% to about 40% and the weight concentration of component B is from about 10% to about 60%.

In another embodiment of the coating composition, the weight % concentration of Component A is from about 40% to about 20% and the weight concentration of component B is from about 60% to about 80%.

In another embodiment of the coating composition, the vapor pressure of Component B is at least 10 ton greater than the vapor pressure of Component A.

In another embodiment of the coating composition, the polymer resin is selected from the group consisting of a polyhydroxystyrene resin, a novolac resin, an acrylic resin, an epoxy resin, an isoprene resin, and a methacrylic resin.

In another embodiment of the coating composition, the polymer resin content is at least 5 wt %.

Yet another embodiment concerns a method for coating a semiconductor wafer. The method comprises contacting said wafer with a composition which comprises a polymer, a primary solvent or mixture of primary solvents (Component A) at a weight % concentration ranging from 1 to 99%, and a co-solvent or mixture of co-solvents (Component B) at a weight range % concentration ranging from 99-1%. Moreover, the vapor pressure of Component B is greater than the vapor pressure of Component A, and Component B is selected from the group consisting of methyl acetate, ethyl acetate, isopropyl acetate, methyl propionate, ethyl propionate, acetone, methyl ethyl ketone, methyl propyl ketone, and mixtures thereof.

In another embodiment of the method, the weight % concentration of Component A is from about 90% to 40% and the weight concentration of component B is from about 10% to about 60%.

In another embodiment of the method, the weight % concentration of Component A is about from 40% to about 20% and the weight concentration of component B is from about 60% to about 80%.

In another embodiment of the method, the vapor pressure of Component B is at least 10 ton greater than the vapor pressure of Component A.

In another embodiment of the method, the polymeric resin is selected from the group consisting of a polyhydroxystyrene resin, a novolac resin, an acrylic resin, an epoxy resin, an isoprene resin, and a methacrylic resin.

In another embodiment of the method, said contacting is via a spin-coating operation at conditions sufficient to deposit thick films of the polymeric material.

In another embodiment of the method, said contacting is via a spray-coating operation at conditions sufficient to deposit thick films of the polymeric material.

### BRIEF DESCRIPTION OF THE FIGURES

FIG. 1 shows the increase in novolac and polyhydroxystyrene film thickness with increasing concentration of methyl acetate and solution vapor pressure and demonstrates the uniformity of such film thickness measured at center and edge for spin coatings prepared with various mixtures of methyl acetate and PM Acetate (propylene glycol monomethyl ether acetate);

FIG. 2 shows the increase in novolac and polyhydroxystyrene film thickness with increasing concentration of methyl acetate and solution vapor pressure and demonstrates the uniformity of such film thickness measured at center and edge for spin coatings prepared with various mixtures of methyl acetate and PM solvent (propylene glycol monomethyl ether);

FIG. 3 shows the increase in novolac and polyhydroxystyrene film thickness with increasing concentration of methyl acetate and solution vapor pressure and demonstrates the uniformity of such film thickness measured at center and edge for spin coatings prepared with various mixtures of methyl acetate and MPK (methyl n-propyl ketone);

FIG. 4 shows the increase in novolac and polyhydroxystyrene film thickness with increasing concentration of methyl acetate and solution vapor pressure and demonstrates the uniformity of such film thickness measured at center and edge for spray coatings prepared with various mixtures of methyl acetate and PM Acetate (propylene glycol monomethyl ether acetate);

FIG. 5 shows the increase in novolac and polyhydroxystyrene film thickness with increasing concentration of methyl acetate and solution vapor pressure and demonstrates the uniformity of such film thickness measured at center and edge for spray coatings prepared with various mixtures of methyl acetate and PM solvent (propylene glycol monomethyl ether);

FIG. 6 shows the increase in novolac and polyhydroxystyrene film thickness with increasing concentration of methyl acetate and solution vapor pressure and demonstrates the uniformity of such film thickness measured at center and edge for spray coatings prepared with various mixtures of methyl acetate and MPK (methyl n-propyl ketone);

FIG. 7 shows the relationship of solution vapor pressure effected by the addition of acetone and methyl acetate and film thickness for various mixtures of novolac and polyhydroxystyrene in methyl n-propyl ketone; and

FIG. 8 shows the relationship of solution viscosity affected by the addition of methyl acetate and film thickness for various mixtures of novolac and polyhydroxystyrene in PM Acetate (propylene glycol monomethyl ether acetate).

### DETAILED DESCRIPTION OF THE INVENTION

In accordance with a first aspect, the present invention provides carrier solvent compositions for the production of thick films of polymeric material on a substrate. The coating compositions include a co-solvent, for example methyl acetate, in conjunction with other solvents and a resin. In accordance with further aspects of the invention, the co-solvent concentration may vary from about 1% to about 99% by weight of the solvent portion of the composition.

In accordance with a further aspect of the invention, methods of depositing a polymeric material onto a substrate are provided. The methods include puddle-spin and spray-spin coating with a composition comprising preferably methyl acetate in conjunction with other solvents necessary to deposit thick films of the polymeric material.

The compositions and methods have particular applicability to semiconductor wafer fabrication, for example, in the coating of thick films of photoresist onto semiconductor wafers. Thick photoresist films are necessary at a variety of process steps to include thicker layers for ion-implantation during front-end gate transistor processing, and ultra-thick films for wafer level packaging solder bumping. The compositions and methods are particularly suitable for the deposition of polymeric systems which utilize PHost, novolac, acrylic, epoxy, isoprene, and methacrylic varieties of resins.

The terms “coating” and “deposition” are used interchangeably throughout this specification. Similarly, the terms “carrier solvents”, “carrier solvent mixtures”, “carrier solvent composition”, and “carrier solvent systems” are used interchangeably. Likewise, the terms “resist” and “photoresist” are used interchangeably. For purposes of this specification, which describes the inventions surrounding carrier solvents and methods of coating, the use of the terms “polymer” and “polymeric” may represent “photoresist” and other similar “built” or “final-form” systems, at least from the perspective of measured thickness. The indefinite articles “a” and “an” are intended to include both the singular and the plural. All ranges are inclusive and combinable in any order except where it is clear that such numerical ranges are constrained to add up to 100%. The terms “weight percent” or “wt %” mean weight percent based on the total weight of the coating composition, unless otherwise indicated. Vapor pressure, measured in units of torr (T) at 20° C., for referenced solvents is readily available from various chemical property handbooks and websites. The term “thickness” and “thick” when used to describe the physical property of the coating as measured on a contact profilometer or similar equipment, is intended to represent values in Angstroms (Å) or microns (um)

The present invention provides carrier solvent compositions which can effectively deposit thick films of polymeric organic substances onto a substrate, for example, an electronic device substrate such as a wafer, which may exhibit irregular topography that includes various layers and structures such as metal, semiconductor, dielectric and polymeric materials. Typical semiconductor wafer materials include, for example, materials such as silicon, gallium arsenide, indium phosphide, and sapphire materials.

The carrier solvent compositions are multi-component systems to include primary solvent(s) (Component A) in conjunction with other compatible co-solvent(s) or mixtures thereof (Component B) in the presence of common varieties of polymeric resins used in photoresist, dielectrics, and adhesives for semiconductor processing. These compositions are typically anhydrous or substantially anhydrous (<1 wt % moisture), aiding in solubility of the polymeric resin and casting performance during the coating practice. Proper selection and determination of the carrier solvent compositions can substantially aid in depositing thick films of polymeric material, thereby allowing for simplified processing (i.e. fewer coatings), higher throughput, waste reduction, and ultimately an option to reduce costs.

The carrier solvent compositions include one or more primary solvents (Component A) of the varieties which include one or more esters selected from the group consisting of structures (I) R—CO₂R₁, glycol ether esters of structures (II) R₂—CO₂C₂H₄—OC₂H₄—OR₃, (III) R₄—CO₂C₃H₆OC₃H₆—OR₅ and (IV) R₆OCO₂R₇, alcohols selected from structures (V) R₈OH, (VI) R₉OC₂H₄OC₂H₄OH, (VII) R₁₀OC₃H₆OC₃H₆OH, (VIII) R₁₁OC₂H₄OH, and (IX) R₁₂OC₃H₆OH, ketones selected from structures (X) R₁₃COR₁₄, sulfoxides selected from structure (XI) R₁₅SOR₁₆, and amides such as N,N-dimethyl formamide, N,N-dimethyl acetamide, and N-methyl pyrolidone, wherein R, R₁, R₂, R₃, R₄, R₅, R₆, R₇, R₈, R₉, R₁₀, R₁₁, R₁₂, R₁₃, R₁₄, R₁₅, and R₁₆ are independently selected from C₁-C₁₄-alkyl groups; wherein R, R₁, R₁₃, R₁₄ may be selected from C₁ to C₈ alkyl groups, but with the provision that both R and R₁ cannot represent a methyl group and both R₁₃ and R₁₄ cannot represent a methyl group.

Further, suitable primary solvents (Component A) include, but are not limited to ketones such as cyclohexanone, 2-heptanone, methyl propyl ketone, and methyl amyl ketone, esters such as isopropyl acetate, ethyl acetate, butyl acetate, ethyl propionate, methyl propionate, gamma-butyrolactone (BLO), ethyl 2-hydroxypropionate (ethyl lactate (EL)), ethyl 2-hydroxy-2-methyl propionate, ethyl hydroxyacetate, ethyl 2-hydroxy-3-methyl butanoate, methyl 3-methoxypropionate, ethyl 3-methoxy propionate, ethyl 3-ethoxypropionate, methyl 3-ethoxy propionate, methyl pyruvate, and ethyl pyruvate, ethers and glycol ethers such as diisopropyl ether, ethyleneglycol monomethyl ether, ethyleneglycol monoethyl ether, and propylene glycol monomethyl ether (PGME), glycol ether esters such as ethyleneglycol monoethyl ether acetate, propyleneglycol methyl ether acetate (PGMEA), and propyleneglycol propyl ether acetate, aromatic solvents such as methylbenzene, dimethylbenzene, anisole, and nitrobenzene, amide solvents such as N,N-dimethylacetamide (DMAC), N,N-dimethylformamide, and N-methylformanilide; and pyrrolidones such as N-methylpyrrolidone (NMP), N-ethylpyrrolidone (NEP), dimethylpiperidone, 2-pyrrole, N-hydroxyethyl-2-pyrrolidone (HEP), N-cyclohexyl-2-pyrrolidone (CHP), and sulfur containing solvents such as dimethyl sulfoxide, dimethyl sulfone and tetramethylene sulfone. These organic solvents may be used either individually or in combination (i.e., as mixtures with others).

The carrier solvent composition further includes one or more co-solvents (Component B) as distinguished from the primary solvent (Component A) by having a vapor pressure of at least 10 ton greater than the vapor pressure of the primary solvent at 20° C., thus enhancing the system's evaporative properties. Suitable co-solvents (Component B) include, but are not limited, to, esters such as methyl acetate, ethyl acetate, isopropyl acetate, methyl propionate, and ethyl propionate, and ketones such as acetone, methyl ethyl ketone, and methyl propyl ketone.

The co-solvent is typically added at the end of the formulation process. For example, when preparing a polymer mixture using a carrier solvent system, the typical process sequence would first add the polymeric material directly to the primary solvent (Component A=low vapor pressure) and mix to homogeneity. Once mixing is complete, the co-solvent (Component B) is added to finish the coating composition. The exact order and conditions for mixing may vary depending on the material and the sample size. The co-solvent is typically present in a carrier solvent composition in an amount of from about 1% to about 99 wt %, from about 40% to about 90 wt % or even from about 60% to about 80% based on the total weight of the carrier solvents.

The polymers which represent the focus of this invention comprise resins of polyhydroxystyrene (PHost) and novolac. PHost can be any single polymer or copolymer of vinylphenol, acrylate derivatives, acrylonitrile, methacrylates, methacrylonitrile, styrene, or derivatives thereof such as a- and p-methylstyrene, and hydrogenated resins derived from vinylphenol and acrylate derivatives. Substituted PHost includes alkali suppressing groups that represent the de-coupling reaction with chemical-amplification processes. Common PHost materials may include PB5 and PB5W (Hydrite Chemical Co., Brookfield Wis.).

Novolac resins of the present invention are those that have been commonly used in the art of photoresist manufacture as exemplified by “Chemistry and Application of Phenolic Resins”, Knop A. and Scheib, W.; Springer Verlag, New York, 1979 in Chapter 4. Novolac resins of the present invention typically are derived from phenolic compounds such as cresols and xylenols. Common novolac materials include product number 5200 and 3100 under the tradename Rezicure (SI Group, Schenectady, N.Y.).

When using a co-solvent such as methyl acetate at a concentration between 40-90 wt %, the balance of the carrier system will be provided by one or more of the primary solvents. This carrier solvent mix is blended with organic resins and solids to comprise the corresponding polymeric coating. The solids in this polymeric coating may be present from about 5 to 50 wt % of the final mixture. For example, to prepare 100 kg with 20% polymeric content and 60% co-solvent content (i.e. methyl acetate), the final mixture would require the following: 20 kg solids+48 kg methyl acetate (80 kg×60%)+32 kg balance primary solvents (80 kg×40%).

In accordance with a further aspect of the invention, methods of depositing thick film polymeric materials onto a substrate are provided. The coating compositions are useful for the deposition of various types of polymeric organic substances, for example, PHost or novolac resins, such as are present in positive-type photoresists commonly used in semiconductor device fabrication in front-end and back-end-of-line processes. These polymeric materials may be applied by the act of spin-coating or spray-coating. Once the films are produced through conventional practice through a soft bake stage, the film thickness is measured. As stated previously in this document, the coating of thicker films is possible by increasing solids content in the resin formula or lowering spin-speed on the tool. Alternatively, this invention describes a method of depositing thick polymer coatings by using high vapor pressure carrier solvent systems. In this manner, greater process control may be offered to achieve thick films. Namely, systems which represent this invention are able to achieve a thickness increase by factors of 2-3 using mixtures of identical solids and tool conditions. What is noteworthy is that coating systems of this invention commonly exhibit lower viscosity, yet yield increased coating thickness while maintaining desired coating performance. Additional film thickness may be achieved by further increase in solids loading to the coating composition and/or adjusting spin speed.

An advantage of the compositions and methods of the present invention is that they may be effectively used to deposit thick films of polymeric material in a uniform manner onto inorganic substrates which provides a significant benefit over conventional systems. Further advantage is gained by using methyl acetate as the most preferred co-solvent in the present invention which allows for additional control in coating operations by reducing the viscosity of the coating compositions. For example, depositing PHost and novolac resins using a methyl acetate rich carrier solvent system at >60 wt % methyl acetate will represent a thickness increase by a factor of 2-3.

### EXAMPLES

The following examples are presented to illustrate further various aspects of the present invention, but are not intended to limit the scope of the invention in any aspect.

### Example 1

Concentrations of resin at 10% wt were prepared in a range of solvents with methyl acetate addition at increments of 20%. The solvents tested included: PMA—propyleneglycol monomethylether acetate, PM—propyleneglycol monomethylether, and MPK—methyl n-propyl ketone. These solutions are then applied by spin-coating practice to silicon test wafers (100 mm diameter). The coating system used was a Brewer Science CEE CB-100, conducted at a rotation speed of 1000 rpm for 60 sec and followed by a 1 min soft bake at 10° C. Thickness was determined by duplicate measurement at the center and edge of the coated test wafer using a contact profilometer of the variety, Ambios XP-1. The vapor pressure of carrier solvent compositions was calculated using Raoult's law using the standard vapor pressure of referenced solvents at 20° C. The results are shown below in Table 1. TABLE 1. Thickness measured in angstroms of spin coated films of novolac (N) resin and PHost (PH) resin. Measurements are conducted at center (C) and edge (E). All values represent the average of duplicate measurements. Uniformity is measured as % variation (VAR) across the wafer. Primary solvents are: PM Acetate—propyleneglycol monomethylether acetate, PM—propyleneglycol monomethylether, MPK—methyl n-propyl ketone. ¹Balance of solvent wt % is methyl acetate. ²Calculated using Raoult's Law.

TABLE 1

| Novolac Resin (10% Solids)- SPIN | | | | | PHost Resin (10% Solids)- SPIN | | | | |
|---|---|---|---|---|---|---|---|---|---|
| Solvent | | | | | Solvent | | | | |
| Percent | | | | ²Vapor | Percent | | | | ²Vapor |
| ¹PM | Center | Edge | Percent | Pressure | ¹PM | Center | Edge | Percent | Pressure |
| Acetate | (Å) | (Å) | Variation | (Torr) | Acetate | (Å) | (Å) | Variation | (Torr) |
| 100% | 3841 | 3838 | 0.1% | 3.7 | 100% | 2593 | 2698 | 3.9% | 3.7 |
| 80% | 4915 | 4764 | 3.1% | 57.6 | 80% | 3608 | 3553 | 1.5% | 57.6 |
| 60% | 6847 | 6570 | 4.0% | 98.6 | 60% | 4570 | 4735 | 3.5% | 98.6 |
| 40% | 8757 | 8660 | 1.1% | 130.1 | 40% | 7050 | 6747 | 4.3% | 130.1 |
| 20% | 10565 | 9728 | 7.9% | 156.8 | 20% | 8113 | 7747 | 4.5% | 156.8 |
| 0% | 10112 | 9971 | 1.4% | 178.3 | 0% | 7076 | 6990 | 1.2% | 178.3 |
| | | | | ²Vapor | | | | | ²Vapor |
| ¹PM | Center | Edge | Percent | Pressure | ¹PM | Center | Edge | Percent | Pressure |
| Solvent | (Å) | (Å) | Variation | (Torr) | Solvent | (Å) | (Å) | Variation | (Torr) |
| 100% | 5743 | 5722 | 0.4% | 8 | 100% | 4178 | 4161 | 0.4% | 8 |
| 80% | 6798 | 6994 | 2.8% | 47.7 | 80% | 4516 | 4996 | 9.6% | 47.7 |
| 60% | 8708 | 8685 | 0.3% | 84.3 | 60% | 6474 | 6279 | 3.0% | 84.3 |
| 40% | 10535 | 10074 | 4.4% | 118.0 | 40% | 7942 | 7713 | 2.9% | 118.0 |
| 20% | 10373 | 10202 | 1.6% | 149.3 | 20% | 8469 | 8062 | 4.8% | 149.3 |
| 0% | 10112 | 9971 | 1.4% | 178.3 | 0% | 7076 | 6990 | 1.2% | 178.3 |
| | | | | ²Vapor | | | | | ²Vapor |
| | Center | Edge | Percent | Pressure | | Center | Edge | Percent | Pressure |
| ¹MPK | (Å) | (Å) | Variation | (Torr) | ¹MPK | (Å) | (Å) | Variation | (Torr) |
| 100% | 4909 | 4674 | 4.8% | 27.8 | 100% | 3859 | 3929 | 1.8% | 27.8 |
| 80% | 5931 | 5759 | 2.9% | 61.7 | 80% | 4655 | 4505 | 3.2% | 61.7 |
| 60% | 6926 | 6723 | 2.9% | 93.5 | 60% | 5177 | 5521 | 6.2% | 93.5 |
| 40% | 8088 | 7712 | 4.6% | 123.5 | 40% | 6315 | 6174 | 2.2% | 123.5 |
| 20% | 8922 | 8373 | 6.2% | 151.7 | 20% | 6968 | 6695 | 3.9% | 151.7 |
| 0% | 10112 | 9971 | 1.4% | 178.3 | 0% | 7076 | 6990 | 1.2% | 178.3 |

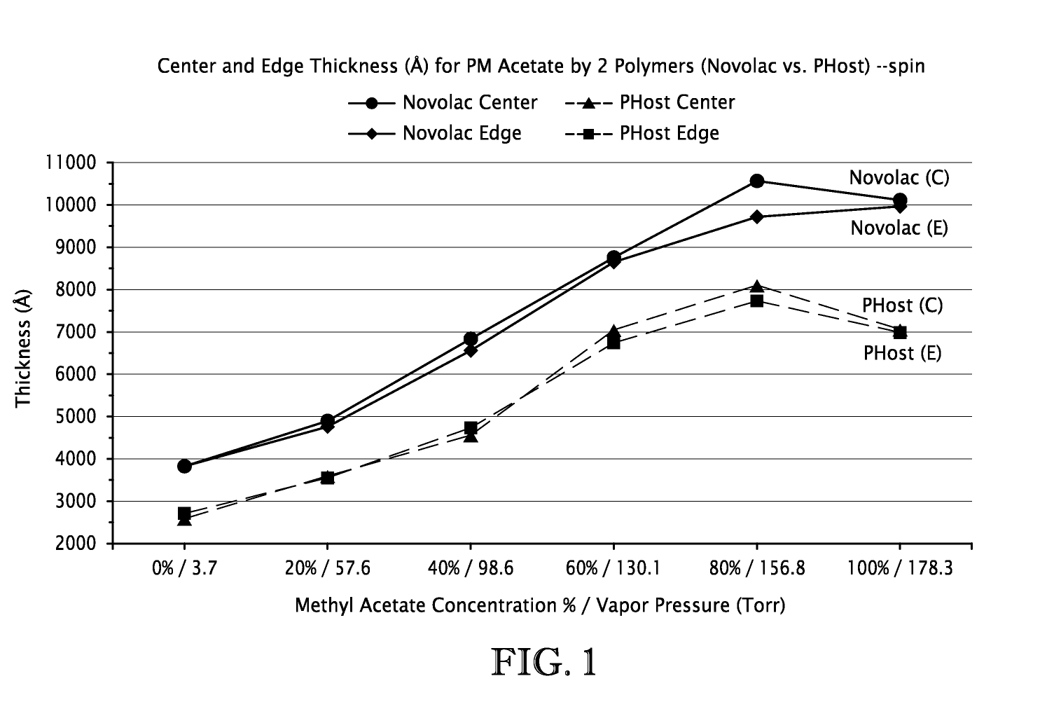

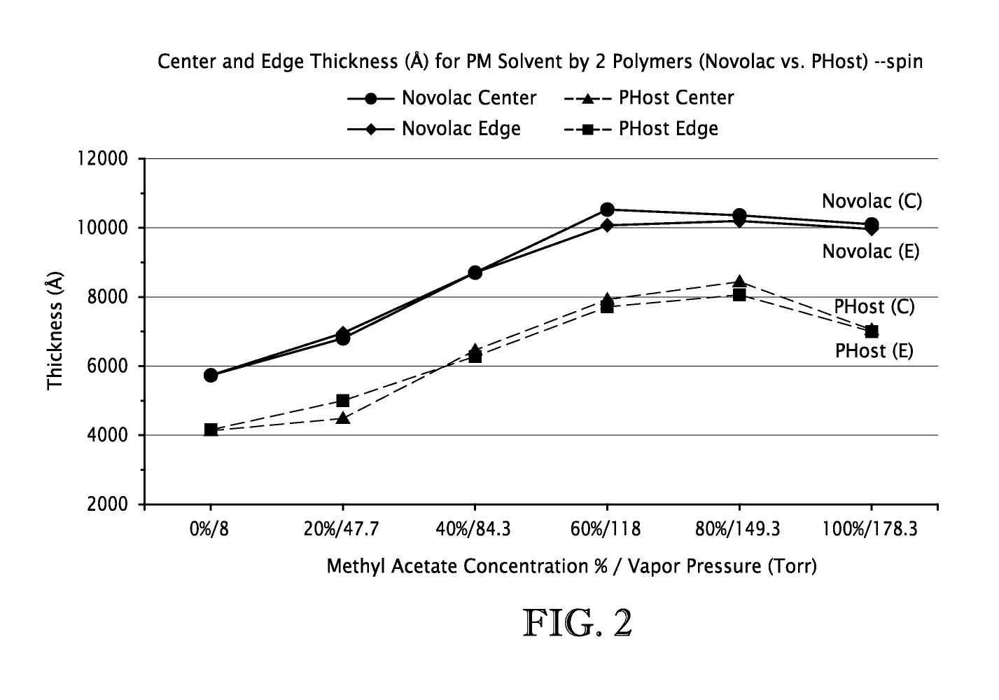

The data shown in Table 1 indicate a thickness increase with increasing methyl acetate addition. At values of 60% and higher, the thickness values show the greatest change. Uniformity is <5% for most of the solvent systems, relative averaging comparison. FIGS. 1 through 3 demonstrate the surprising increase in coating thickness by increasing the concentration of a co-solvent such as methyl acetate in common primary solvents used in the application of coating compositions.

### Example 2

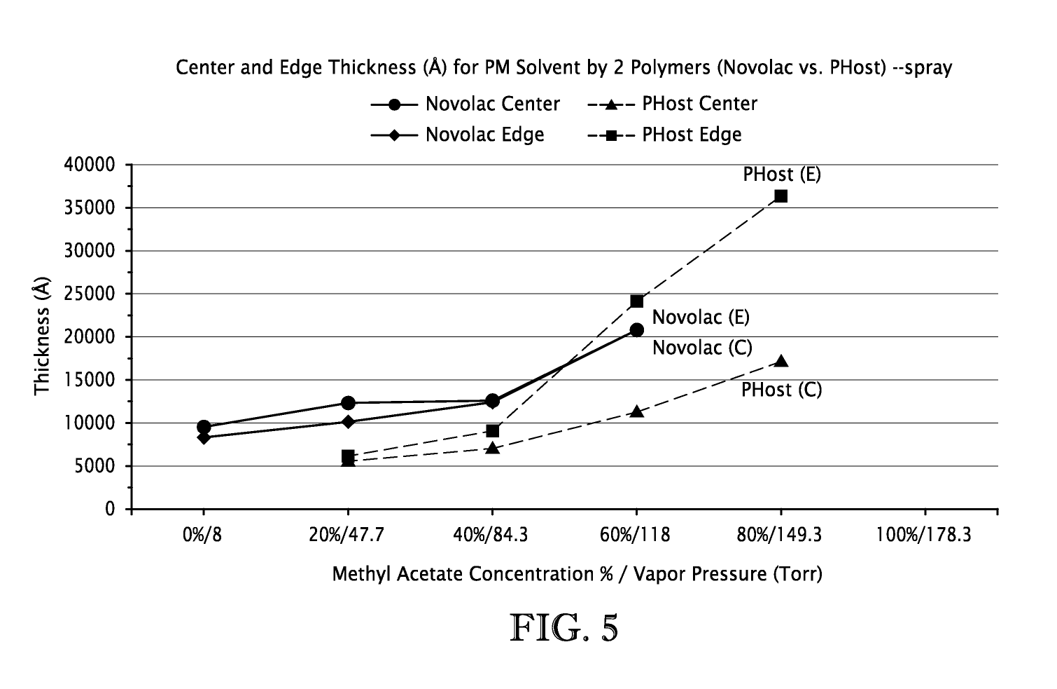

Similar to example 1, solutions of PMA, PM and MPK with methyl acetate were then spray coated onto wafers using the same set-up with the equipment with an air-driven sprayer. Substrates, spin condition, soft-bake, and amounts were all the same as in the previous test. The results are shown in Table 2. At higher levels of methyl acetate, spray performance was not measurable due to rapid evaporation at the spray nozzle. As noted in Table 2 and FIG. 5, 10% PHost resin PM solvent displayed viscosity too high for use in the spray apparatus, but addition of methyl acetate reduced viscosity sufficiently to obtain coatings in medium range of methyl acetate concentrations thus demonstrating the advantage of viscosity reduction.

TABLE 2

| Novolac Resin (10% Solids)- SPRAY | | | | | PHost Resin (10% Solids)- SPRAY | | | | |
|---|---|---|---|---|---|---|---|---|---|
| Solvent | | | | | Solvent | | | | |
| Percent | | | | Vapor | Percent | | | | Vapor |
| PM | Center | Edge | Percent | Pressure | PM | Center | Edge | Percent | Pressure |
| Acetate | (Å) | (Å) | Variation | (Torr) | Acetate | (Å) | (Å) | Variation | (Torr) |
| 100% | 5403 | 4150 | 30.2% | 3.7 | 100% | 2965 | 3353 | 11.6% | 3.7 |
| 80% | 5781 | 5572 | 3.6% | 57.6 | 80% | 4209 | 4322 | 2.6% | 57.6 |
| 60% | 10823 | 8469 | 21.7% | 98.6 | 60% | 6228 | 6515 | 4.4% | 98.6 |
| 40% | 14681 | 13425 | 8.6% | 130.8 | 40% | 11652 | 12948 | 10% | 130.8 |
| 20% | 44396 | 53677 | 17.3% | 156.8 | 20% | NA | NA | NA | 156.8 |
| 0% | NA | NA | NA | 178.3 | 0% | NA | NA | NA | 178.3 |
| | | | | Vapor | | | | | Vapor |
| PM | Center | Edge | Percent | Pressure | PM | Center | Edge | Percent | Pressure |
| Solvent | (Å) | (Å) | Variation | (Torr) | Solvent | (Å) | (Å) | Variation | (Torr) |
| 100% | 9464 | 8363 | 11.6% | 8 | 100% | NA | NA | NA | 8 |
| 80% | 12263 | 10169 | 17.1% | 47.7 | 80% | 5649 | 6130 | 7.8% | 47.7 |
| 60% | 12573 | 12409 | 1.3% | 84.3 | 60% | 7149 | 9053 | 21.0% | 84.3 |
| 40% | 20747 | 20759 | 0.1% | 118 | 40% | 11397 | 24142 | 52.8% | 118 |
| 20% | NA | NA | NA | 149.3 | 20% | 17246 | 36403 | 52.6% | 149.3 |
| 0% | NA | NA | NA | 178.3 | 0% | NA | NA | NA | 178.3 |
| | | | | | | | | | Vapor |
| | | | | | | Center | Edge | Percent | Pressure |
| | | | | | MPK | (Å) | (Å) | Variation | (Torr) |
| | | | | | 100% | 5809 | 6008 | 3.3% | 27.8 |
| | | | | | 80% | 6323 | 7073 | 10.6% | 61.7 |
| | | | | | 60% | 10775 | 10741 | 0.3% | 93.5 |
| | | | | | 40% | 13128 | 24007 | 45.3% | 123.5 |
| | | | | | 20% | NA | NA | NA | 151.7 |
| | | | | | 0% | NA | NA | NA | 178.3 |

TABLE 2. Thickness measured in angstroms of spray coated films of novolac (N) resin and PHost (PH) resin. Measurements are conducted at center (C) and edge (E). All values represent the average of duplicate measurements. Uniformity is measured as % variation (VAR) across the wafer. Primary solvents are: PM Acetate—propyleneglycol monomethylether acetate, PM—propyleneglycol monomethylether, MPK—methyl n-propyl ketone. ¹Balance of solvent wt % is methyl acetate.

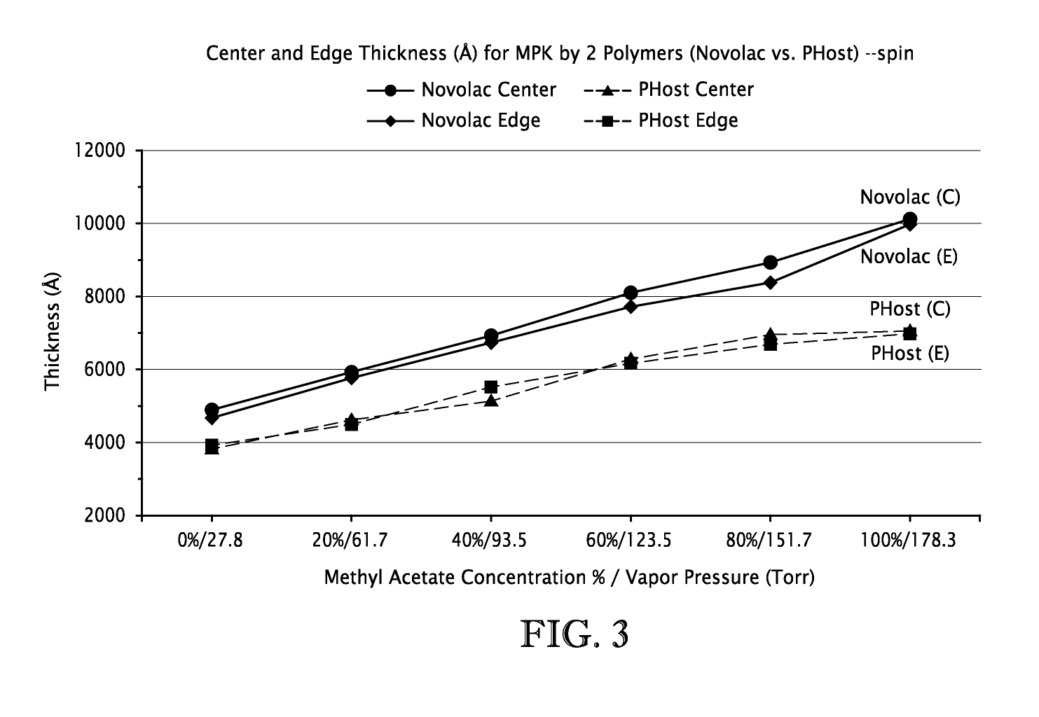

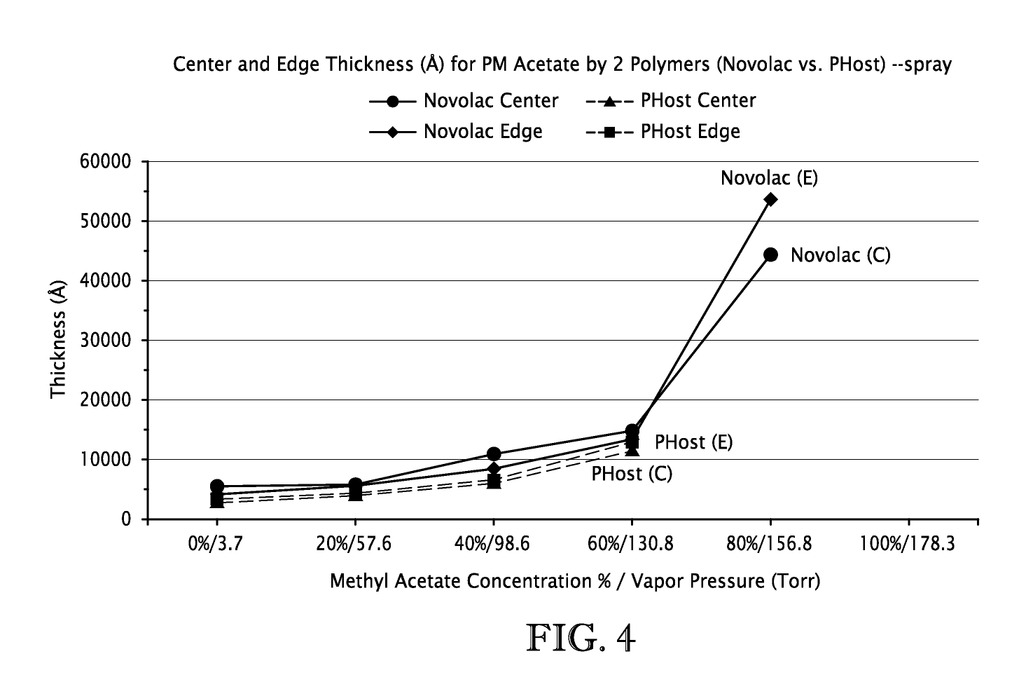

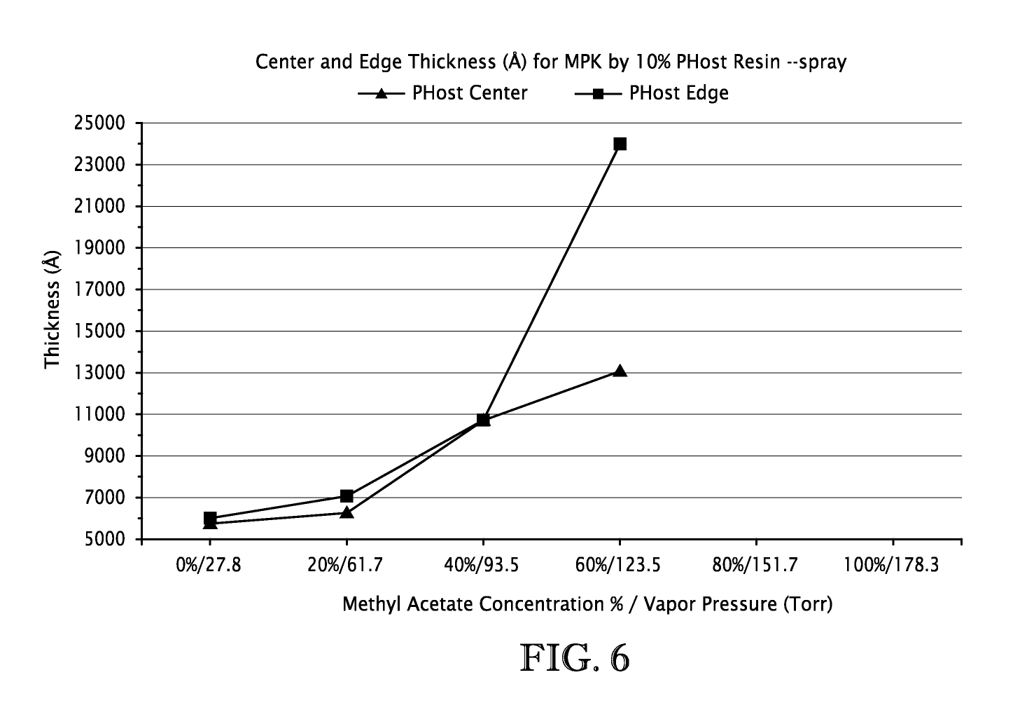

FIGS. 4, 5 and 6 indicate the spray condition for thickness is significantly higher over that for spin-coating. As shown before, spray-coating methods along with methyl acetate enrichment results in a 2-3 fold increase over similar conditions for spin-coating. When spray coating, low concentrations of methyl acetate offer similar results as spin-coating. When methyl acetate reaches a concentration of 60% wt, relative to the remaining solvent, center to edge uniformity is compromised. This value of 60% wt corresponds to values of vapor pressures of the system of ≧100 Torr, as calculated by Raoult's law (see FIGS. 3 & 4) which may limit the effectiveness of spray coating techniques using PHost resin.

### Example 3

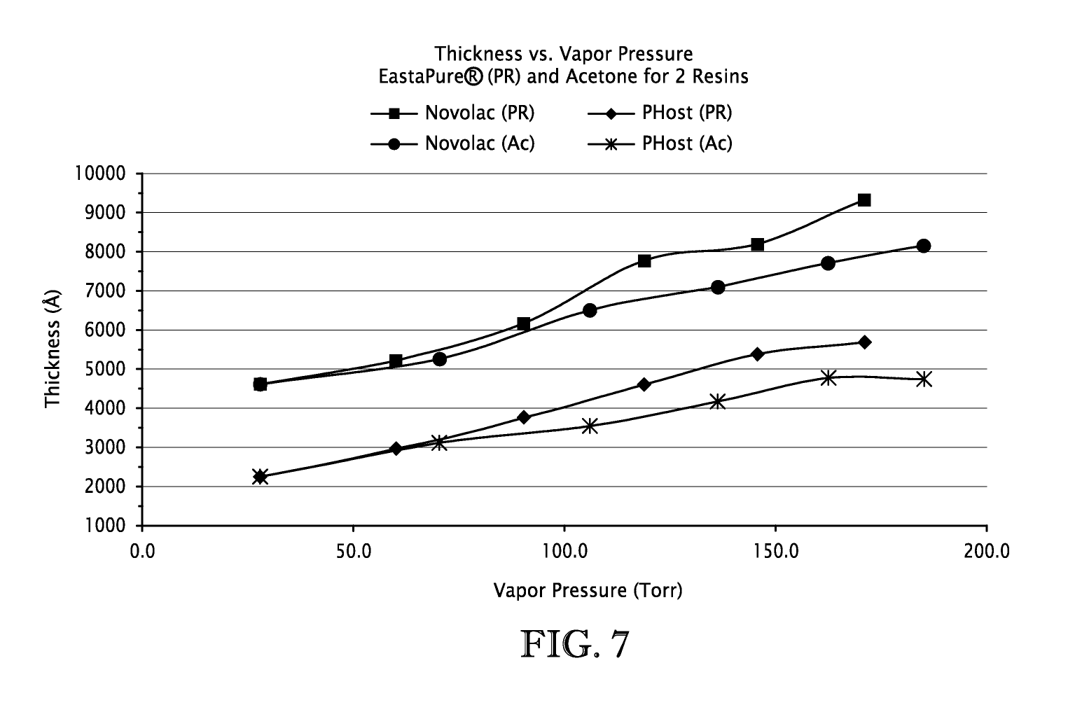

Similar to example 1, solutions of MPK with methyl acetate and acetone were spin coated onto wafers using the same set-up with the equipment as described previously. Substrates, spin condition, soft-bake, and amounts were all the same as in Example 1. The results are shown in graphs depicted in FIG. 7 for MPK and methyl acetate and MPK and acetone.

Observing FIG. 7 suggests that acetone may have a similar effect as methyl acetate in producing thick films, however, methyl acetate surprisingly does produce thicker films over that of acetone.

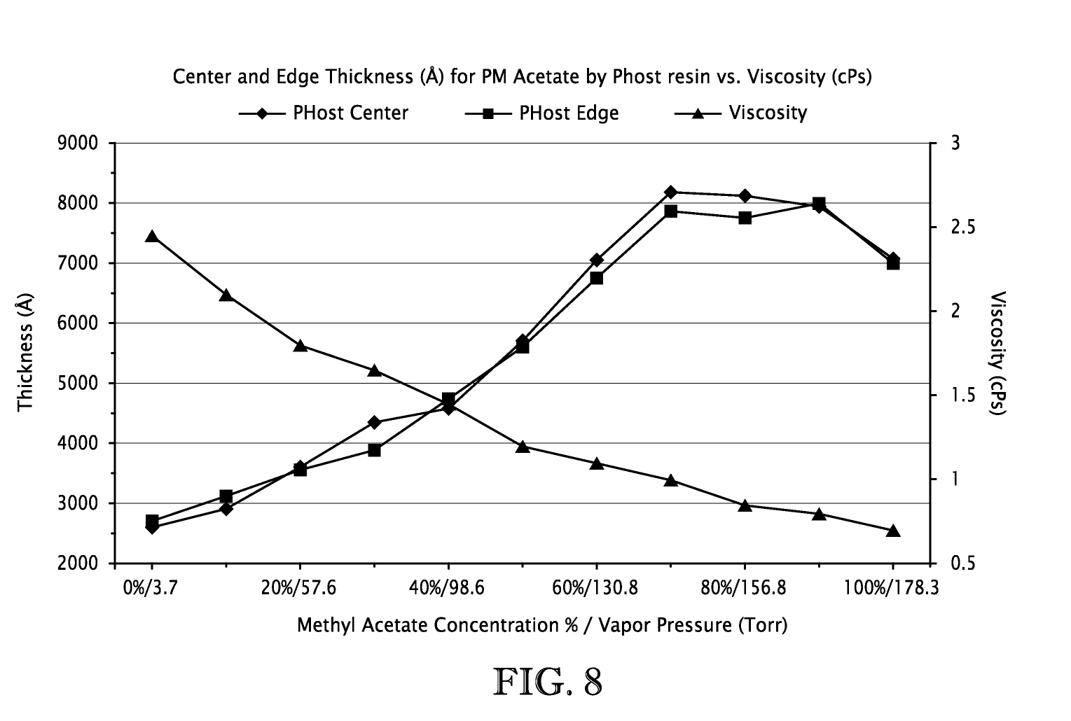

Further studies, as illustrated in FIG. 8 for PHost in PM Acetate, measuring the viscosity of coating compositions show that increasing concentration of methyl acetate not only facilitates thicker film formation, but also provides for lower viscosity coating solution. This likewise is a general observation for all commonly used resins and coating solvents when methyl acetate concentration is increased. Such observation presents those skilled in the art with additional techniques and controls for increasing film thickness.

Having described the invention in detail, those skilled in the art will appreciate that modifications may be made to the various aspects of the invention without departing from the scope and spirit of the invention disclosed and described herein. It is, therefore, not intended that the scope of the invention be limited to the specific embodiments illustrated and described but rather it is intended that the scope of the present invention be determined by the appended claims and their equivalents.

What is claimed is:

1. A method for coating a semiconductor wafer comprising, spin coating said semiconductor wafer with a coating composition comprising:
a polymer,
a carrier solvent composition comprising:
a primary solvent or mixture of primary solvents (Component A) at a wt % concentration ranging from about 1% to about 99 wt % based on the weight of the carrier solvent composition, and
methyl acetate in a wt % concentration ranging from about 99% to about 1 wt % based on the weight of the carrier solvent composition, and
wherein the vapor pressure of methyl acetate is greater than the vapor pressure of Component A.

2. The method of claim 1, wherein the wt % of Component A ranges from about 60% to about 99 wt % based on the weight of the carrier solvent composition, and the wt % of methyl acetate ranges from about 1% to about 40 wt % based on the weight of the carrier solvent composition.

3. The method of claim 1, wherein the vapor pressure of methyl acetate is at least 10 torr greater than the vapor pressure of Component A.

4. The method of claim 1, wherein the polymeric resin is selected from the group consisting of a polyhydroxystyrene resin, a novolac resin, an acrylic resin, an epoxy resin, an isoprene resin, and a methacrylic resin.

5. The method of claim 1, wherein Component A comprises one or more solvents selected from the group consisting of structures (I) R—CO₂R₁, (II) R₂—CO₂C₂H₄OC₂H₄—OR₃, (III) R₄OCO₂R₅, (IV) R₆OH₅ (V) R₇OC₂H₄OC₂H₄OH, (VI) R₈OC₂H₄OH₅ and (VII) R₉COR₁₀; wherein R, R₁, R₂, R₃, R₄, R₅, R₆, R₇, R₈, R₉, and R₁₀ are independently selected from C₁-C₈-alkyl groups; wherein R, R₁, R₉, R₁₀ are independently selected from C₁ to C₈ alkyl groups, but with the provision that both R and R₁ cannot represent a methyl group and both R₉ and R₁₀ cannot represent a methyl group.

6. The method of claim 1, wherein component A comprises one or more solvents selected from the group consisting of structures (II) R₂—CO₂C₂H₄OC₂H₄—OR₃, (V) R₇OC₂H₄OC₂H₄OH, and (VI) R₈OC₂H₄OH; wherein R₂, R₃, R₇, and R₈ are independently selected from C₁-C₈-alkyl groups.

7. The method of claim 5, wherein component A represents a single solvent.

8. The method of claim 1, wherein the polymer resin comprises a novolac resin in an amount of at least 5 wt % based on the weight of the coating composition.

9. The method of claim 1, wherein the coating composition forms a film of photoresist on the semiconductor wafer.

10. The method of claim 1, wherein the coating composition is spin coated onto the wafer in a front-end gate transistor processing method or for a wafer level packaging solder bumping method.

11. The method of claim 1, wherein the coating composition forms a positive acting photoresist system on the wafer.

12. The method of claim 11, wherein the wherein the resin comprises a PHost or a novolac.

13. The method of claim 1, wherein Component A comprises propylene glycol monomethyl ether acetate, propylene glycol monomethyl ether, ethyleneglycol monomethyl ether, ethyleneglycol monoethyl ether, propylene glycol monomethyl ether, ethyleneglycol monoethyl ether acetate, propyleneglycol methyl ether acetate (PGMEA), propyleneglycol propyl ether acetate or a combination thereof.

14. The method of claim 1, wherein the coating composition forms a photoresist on the wafer, and the photoresist is subjected to a dosage ion implant beam of arsenic, boron, or phosphorous.

15. The method of claim 14, wherein the photoresist is removed using either a plasma asher, a heated piranha chemical strip, or both.

16. The method of claim 1, comprising forming conductive interconnect bump pads on a front surface of the wafer, forming a passivation layer over the bump pads, depositing an under bump metallization (UBM) structure over the passivation layer, and applying a photoresist layer to the wafer.

17. The method of claim 1, wherein the thickness of the wafer is below 50 microns.

18. The method of claim 1, wherein the thickness of the wafer is 600-700 microns.

19. The method of claim 1, wherein the spin coating method comprises a static puddle method.

20. The method of claim 1, wherein the spin coating method is a dynamic method comprising spinning the wafer.

21. The method of claim 1, wherein the wafer comprises a silicon, gallium arsenide, indium phosphide, or sapphire material.

22. The method of claim 1, wherein the coating composition has less than 1 wt % moisture.

23. The method of claim 1, wherein the method comprises depositing the coating composition comprising a PHost or novolac resin on the wafer by a spin coating method, baking the composition to produce a film, and thereby obtaining a film on the wafer that is at least 2 times thicker if compared to a film on a wafer deposited by a coating having the same resin at an increased solids content using the same application method or using a spin coating method having a lower spin speed using a coating composition having the same resin and resin content.

24. The method of claim 1, wherein the coating composition deposited on the wafer forms a film having a thickness that is at least 2 times thicker if compared to a film obtained by depositing a coating on the same wafer under identical spin coating conditions, polymer type and polymer quantity.

25. The method of claim 1, further comprising obtaining a film of said composition on said wafer after completion of spin coating, wherein the polymer is a novolac resin, and said film has a thickness ranging from 6798 Angstroms to 10,535 Angstroms measured at the center.

26. The method of claim 25, wherein the variation in uniformity of said film from center to edge is less than 5%.

27. The method of claim 1, further comprising obtaining a film of said composition on said wafer after completion of spin coating, wherein the polymer is a PHost resin, and said film has a thickness ranging from 4516 Angstroms to 84693 Angstroms measured at the center.

28. The method of claim 27, wherein the variation in uniformity of said film from center to edge is less than 5%.
